(19) United States
(12) Patent Application Publication
(10) Pub. No.: US 2009/0242389 A1
(43) Pub. Date: Oct. 1, 2009

(54) METHOD FOR MANUFACTURING MAGNETIC RECORDING MEDIUM

(75) Inventors: Noriyuki Asakura, Higashine (JP); Hideaki Takahoshi, Higashine (JP); Jun Taguchi, Kawasaki (JP); Isatake Kaitsu, Kawasaki (JP); Akira Kikuchi, Higashine (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/409,062

(22) Filed: Mar. 23, 2009

(30) Foreign Application Priority Data
Mar. 28, 2008 (JP) 2008-086843

(51) Int. Cl. C23C 14/14; C23C 14/34

(52) U.S. Cl. 204/192.15; 204/192.1

(57) ABSTRACT

A method for manufacturing a magnetic recording medium including a nonmagnetic substrate, an intermediate layer over the nonmagnetic substrate, and a granular magnetic layer for recording information, disposed on the intermediate layer. The method includes sputtering a Co alloy, a Ti oxide, a Si oxide and a Co oxide simultaneously to form the granular magnetic layer containing Co alloy magnetic particles and an oxide magnetically separating the magnetic particles.

### CROSS-REFERENCE TO RELATED APPLICATIONS

This application is based upon and claims the benefit of priority of the prior Japanese Patent Application No. 2008-086843, filed on Mar. 28, 2008, the entire contents of which are incorporated herein by reference.

### FIELD

The present invention relates to a method for manufacturing a magnetic recording medium.

### BACKGROUND

In magnetic storages, such as magnetic disk units, a playback head including a tunneling magnetoresistive element or a perpendicular magnetic recording medium is employed to increase the recording density. To further improve the recording density of a magnetic recording medium, medium noise which is caused by inferior magnetic characteristics of the recording medium is preferably reduced, for example, by decreasing the crystal size of a recording layer in the magnetic recording medium or by reducing the magnetic coupling between crystal grains.

In a perpendicular magnetic recording medium recently proposed, to reduce the medium noise, a nonmagnetic material target or a target containing a nonmagnetic material is used to form a magnetic recording layer by sputtering. Thus, the nonmagnetic material is deposited within the boundaries of magnetic particles, forming a granular structure in the recording layer. The granular structure magnetically separates the magnetic particles and thereby reduces the medium noise.

In the recording layer having the granular structure, the nonmagnetic material reduces magnetic interaction between the magnetic particles. The nonmagnetic material is generally a metal oxide. A stable metal oxide can be segregated between the magnetic particles as an oxide. Thus, Ti, Si, Cr, Ta, W, or Nb oxide can magnetically separate the magnetic particles effectively.

However, when the recording layer having the metal oxide granular structure is formed by sputtering, the metal oxide is inevitably decomposed into a metal component and an oxygen component at a certain proportion. The resulting metal component penetrates into the magnetic particles, thus causing a deterioration in the magnetic characteristics of an alloy constituting the magnetic particles. Thus, even when the amount of metal oxide is increased to reduce the magnetic interaction between the magnetic particles, an excessive increase in the amount of metal oxide results in a deterioration in the magnetic characteristics of the magnetic particles. The magnetic interaction between the magnetic particles is therefore not reduced, but the medium noise is increased. Thus, it is difficult to reduce the medium noise by increasing the amount of metal oxide partly because of the decomposition of the metal oxide.

For example, Y. Inaba et al., “Optimization of the SiO₂ Content in CoPtCr—SiO₂ Perpendicular Recording Media for High-Density Recording”, IEEE TRANSACTIONS ON MAGNETICS, Vol. 40, No. 4, July 2004, pp. 2486-2488 reported that the addition of about 8% to about 12% by mole or more SiO₂ reduces the coercive force Hc of a recording layer and does not reduce the magnetic interaction between magnetic particles. In fact, it has been found that, when a recording layer having a granular structure is formed of SiO₂ or TiO₂, the magnetic characteristics deteriorate by the addition of about 8% by mole or more SiO₂ or TiO₂.

It has also been found that the characteristics of a magnetic recording medium at a step of forming a recording layer having a granular structure depends on the type of element to be oxidized. For example, G. Choe et al., “Magnetic and Recording Characteristics of Reactively Sputtered CoPtCr—(Si—O, Ti—O, and Cr—O) Perpendicular Media”, IEEE TRANSACTIONS ON MAGNETICS, Vol. 42, No. 10, October 2006, pp. 2327-2329 reported various characteristics of a magnetic recording medium that includes a recording layer having a granular structure formed by sputtering Si, Ti, or Cr oxide at different oxygen partial pressures. More specifically, the layered structure and characteristics of the magnetic recording medium depend on the oxygen partial pressure in sputtering.

The composition of a magnetic material that forms a recording layer having a granular structure is expressed as follows: for example, when an alloy portion of the magnetic material is formed of Co, Cr, and Pt, and a nonmagnetic material between magnetic particles is SiO₂, the percentages of Co, Cr, Pt, and SiO₂ are expressed by a/(a+b+c+d) atomic %, b/(a+b+c+d) atomic %, c/(a+b+c+d) atomic %, and d/(a+b+c+d)×100% by mole, respectively, wherein a, b, c, and d denote the numbers of Co, Cr, Pt, and Si atoms (the number of 0 atoms is d×2). When the nonmagnetic material contains an oxide of the same element that constitutes the alloy portion, the metal atoms constituting the alloy are differentiated from the atoms constituting the oxide.

A perpendicular magnetic recording medium that includes a CoPt alloy recording layer containing an oxide has been proposed, for example, by Japanese Laid-open Patent Publication No. 2004-310910. A longitudinal magnetic recording medium (i.e., in-plane magnetic recording medium) that includes a recording layer having a granular structure in which CoPt ferromagnetic particles are separated by an oxide has been proposed, for example, by Japanese Laid-open Patent Publication No. 2007-164826.

Hitherto, the amount of metal oxide has been increased to reduce the magnetic interaction between magnetic particles in a recording layer, thereby reducing the medium noise. However, an excessive increase in the amount of metal oxide results in a deterioration in the magnetic characteristics of the magnetic particles. Therefore the medium noise is difficult to reduce. This is partly because, when the recording layer is formed by sputtering, the metal oxide is decomposed into a metal component and an oxygen component, and the metal component penetrates into the magnetic particles.

### SUMMARY

According to an aspect of the invention, a method for manufacturing a magnetic recording medium including a nonmagnetic substrate, an intermediate layer over the nonmagnetic substrate, and a granular magnetic layer for recording information, disposed on the intermediate layer, includes sputtering a Co alloy, a Ti oxide, a Si oxide and a Co oxide simultaneously to form the granular magnetic layer containing Co alloy magnetic particles and an oxide magnetically separating the magnetic particles.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view of a magnetic recording medium according to a first example;

FIG. 2 is a table showing the magnetic characteristics of oxide granular magnetic layers according to the first example and a first comparative example;

FIG. 3 is a graph illustrating the coercive force of an oxide granular magnetic layer according to the first example and the first comparative example;

FIG. 4 is a graph illustrating the coercive force Hc of an oxide granular magnetic layer according to a second example as a function of the amount of CoO added to the oxide granular magnetic layer;

FIG. 5 is a graph illustrating the saturation magnetization of the oxide granular magnetic layer according to the second example as a function of the amount of CoO added to the oxide granular magnetic layer;

FIG. 6 is a cross-sectional view of a magnetic recording medium according to a third example;

FIG. 7 is a graph illustrating the VTM of an oxide granular magnetic layer (first magnetic layer) according to the third example as a function of the amount of CoO added to the oxide granular magnetic layer; and

FIG. 8 is a graph illustrating the VTMs of oxide granular magnetic layers according to a modification of the third example and a third comparative example.

### DESCRIPTION OF EMBODIMENTS

A magnetic recording medium manufactured by a method for manufacturing a magnetic recording medium according to the present invention includes a recording layer over a nonmagnetic substrate. The recording layer includes Co alloy magnetic particles and an oxide that magnetically separates the magnetic particles. More specifically, the recording layer includes a Co alloy, a first oxide containing Ti oxide and Si oxide, and a second oxide containing Co oxide. The first oxide has a lower energy of formation than the second oxide.

For example, the Ti oxide of the first oxide is TiO₂, which is formed by sputtering using a sputtering target containing about 3% to about 9% by mole TiO₂, and the Si oxide of the first oxide is SiO₂, which is formed by sputtering using a sputtering target containing about 3% to about 9% by mole SiO₂. For example, the Co oxide of the second oxide is CoO, which is formed by sputtering using a sputtering target containing about 1% to about 6% by mole CoO. The sputtering target used to form the recording layer may be a single target containing the Co alloy, the first oxide, and the second oxide or at least two targets that each contain at least one selected from the group consisting of the Co alloy, the first oxide, and the second oxide.

A metal oxide for separating magnetic particles is decomposed into a metal component and an oxygen component by sputtering. Even when the oxygen component does not reach a substrate or is desorbed from the substrate, simultaneous sputtering of an appropriate Co oxide allows an oxygen component resulting from the decomposition of the Co oxide to be bound to the metal component resulting from the decomposition of the metal oxide. Thus, the metal oxide is stably segregated between the magnetic particles. The magnetic interaction between the magnetic particles can therefore be reduced without causing a deterioration in the magnetic characteristics of the magnetic particles. This reduces the medium noise. The reduction in medium noise improves the signal-to-noise ratio (SNR) and the read/write (R/W) performance (or R/W characteristics), thus increasing the recording density of the magnetic recording medium. The R/W performance (or R/W characteristics) indicates the performance of the magnetic recording medium, for example, on the basis of the error rate of read data read after a given piece of data is written on the magnetic recording medium a predetermined number of times. The error rate may be defined by the sector error rate, which is defined by the number of error sectors out of the total number of read sectors.

The penetration of Co atoms resulting from the decomposition of the Co oxide into a Co alloy portion of the magnetic particles does not significantly affect the magnetic characteristics of the magnetic recording medium. The standard free energy of formation of Co oxide per mole of oxygen is much higher than the standard free energy of formation of Si oxide or Ti oxide per mole of oxygen. Thus, in the presence of Co atoms, O (oxygen) atoms, Si atoms, and Ti atoms produced by sputtering, Si atoms and Ti atoms are more easily bound to oxygen than Co atoms are, thus stably forming Si oxide or Ti oxide.

A method for manufacturing a magnetic recording medium according to the present invention will be described below by way of examples with reference to the accompanying drawings.

### First Example

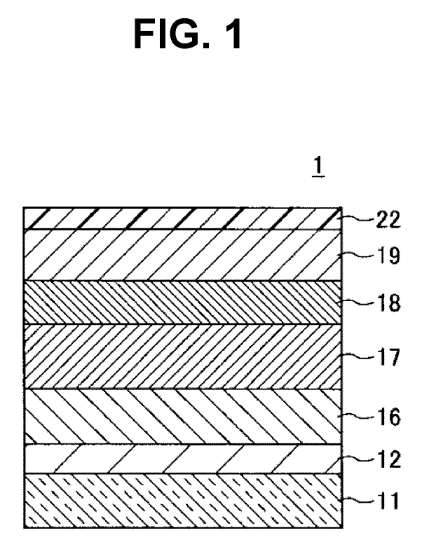

FIG. 1 is a cross-sectional view of a magnetic recording medium according to a first example. In the present example, the present invention is applied to a perpendicular magnetic recording medium. A perpendicular magnetic recording medium 1 included, on a nonmagnetic substrate 11, a CrTi contact layer 12, a NiW seed layer 16, a Ru intermediate layer 17, a nonmagnetic CoCr—SiO₂ granular intermediate layer 18, a (Co₇₂Cr₉Pt₁₉)_{96-x-y}—(TiO₂)ₓ—(SiO₂)_{y}—(CoO)₄ oxide granular magnetic layer 19, and a diamond-like-carbon (DLC) protective layer 22. The amounts of TiO₂ and SiO₂ added to the oxide granular magnetic layer 19 were varied. More specifically, sputtering targets containing different amounts of TiO₂ and SiO₂ were used to form the oxide granular magnetic layer 19. When a single sputtering target is used to form the oxide granular magnetic layer 19, the Co content of the oxide granular magnetic layer 19 (or sputtering target) is expressed by 72×(96−x−y)/100 atomic %. The Cr and Pt contents are expressed in the same manner. That is, the Cr content of the oxide granular magnetic layer 19 (or sputtering target) is expressed by 9×(96−x−y)/100 atomic %, and the Pt content is expressed by 19×(96−x−y)/100 atomic %. The oxide granular magnetic layer 19 (or sputtering target) contained x % by mole TiO₂, y % by mole SiO₂, and 4% by mole CoO.

The nonmagnetic substrate 11 may be a glass substrate, an Al substrate coated with NiP, a plastic substrate, or a Si substrate. The thicknesses were 5 nm for the CrTi contact layer 12, 8 nm for the NiW seed layer 16, 20 nm for the Ru intermediate layer 17, 3 nm for the nonmagnetic CoCr—SiO₂ granular intermediate layer 18, and 8 nm for the (Co₇₂Cr₉Pt₁₉)_{96-x-y}—(TiO₂)ₓ—(SiO₂)_{y}—(CoO)₄ oxide granular magnetic layer 19. Experimental results of the present inventors showed that the perpendicular magnetic recording medium 1 had almost identical characteristics when the thicknesses range from 1 to 30 nm for the CrTi contact layer 12, 2 to 20 nm for the NiW seed layer 16, 5 to 30 nm for the Ru intermediate layer 17, 1 to 10 nm for the nonmagnetic CoCr—SiO₂ granular intermediate layer 18, and 5 to 30 nm for the (Co₇₂Cr₉Pt₁₉)_{96-x-y}—(TiO₂)ₓ—(SiO₂)_{y}—(CoO)₄ oxide granular magnetic layer 19.

The DLC protective layer 22 having a thickness of 4 nm was formed by plasma chemical vapor deposition (CVD).

Deposition conditions were as follows: the CrTi contact layer 12 to the (Co₇₂Cr₉Pt₁₉)_{96-x-y}—(TiO₂)ₓ—(SiO₂)_{y}—(CoO)₄ oxide granular magnetic layer 19 were formed by DC magnetron sputtering using an Ar gas as a sputtering gas, and the deposition pressures were 0.67 Pa for the CrTi contact layer 12 and the NiW seed layer 16, 5 Pa for the Ru intermediate layer 17, 3 Pa for the nonmagnetic CoCr—SiO₂ granular intermediate layer 18, and 4 Pa for the oxide granular magnetic layer 19. Experimental results of the present inventors showed that the perpendicular magnetic recording medium 1 had almost identical characteristics when the deposition pressures range from 0.1 to 2.0 Pa for the CrTi contact layer 12 and the NiW seed layer 16 and 0.5 to 15 Pa for the Ru intermediate layer 17 to the oxide granular magnetic layer 19.

The sputtering is not limited to the DC magnetron sputtering and may be DC sputtering or RF sputtering. The sputtering gas is not limited to the Ar gas and may be a Xe gas, a Kr gas, or a Ne gas.

In a first comparative example, a perpendicular magnetic recording medium was produced under the same deposition conditions as in the first example, except that the oxide granular magnetic layer 19 had a composition of (Co₇₂Cr₉Pt₁₉)₈₈—(TiO₂)₈—(CoO)₄ free of SiO₂.

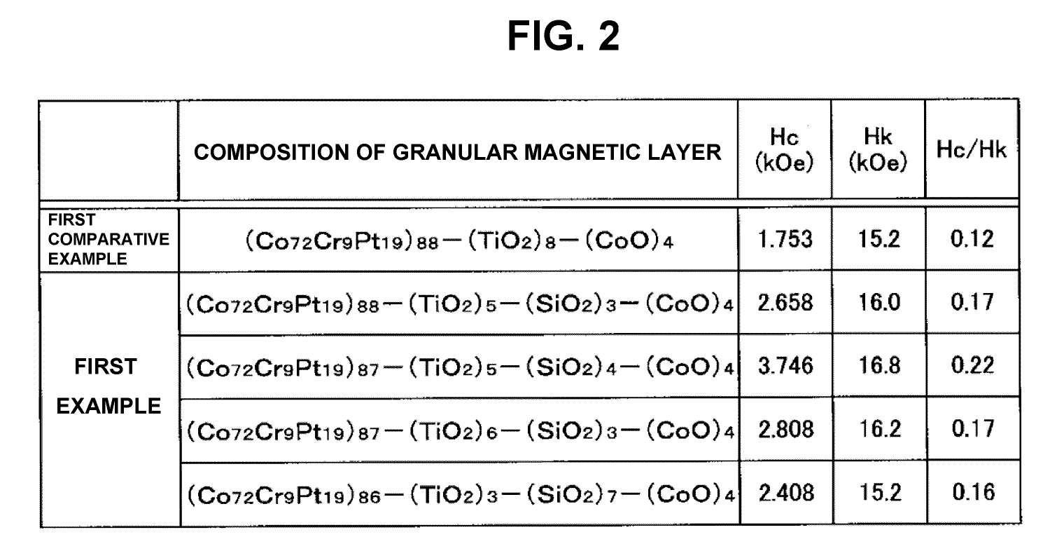

FIG. 2 shows the magnetic characteristics, the coercive force Hc, the anisotropic magnetic field Hk, and their ratio Hc/Hk, of oxide granular magnetic layers according to the first example and the first comparative example. The Hc/Hk indicates the magnetic interaction between magnetic particles in the oxide granular magnetic layer. The oxide granular magnetic layer in the first comparative example had a composition of (Co₇₂Cr₉Pt₁₉)₈₈—(TiO₂)₈—(CoO)₄ free of SiO₂. The oxide granular magnetic layer 19 in the first example had a composition of (Co₇₂Cr₉Pt₁₉)₈₈—(TiO₂)₅—(SiO₂)₃—(CoO)₄, (Co₇₂Cr₉Pt₁₉)₈₇—(TiO₂)₅—(SiO₂)₄—(CoO)₄, (Co₇₂Cr₉Pt₁₉)₈₇—(TiO₂)₆—(SiO₂)₃—(CoO)₄, or (Co₇₂Cr₉Pt₁₉)₈₆—(TiO₂)₃—(SiO₂)₇—(CoO)₄. In the first example, the target contained about 3% to about 7% by mole TiO₂ and about 3% to about 7% by mole SiO₂.

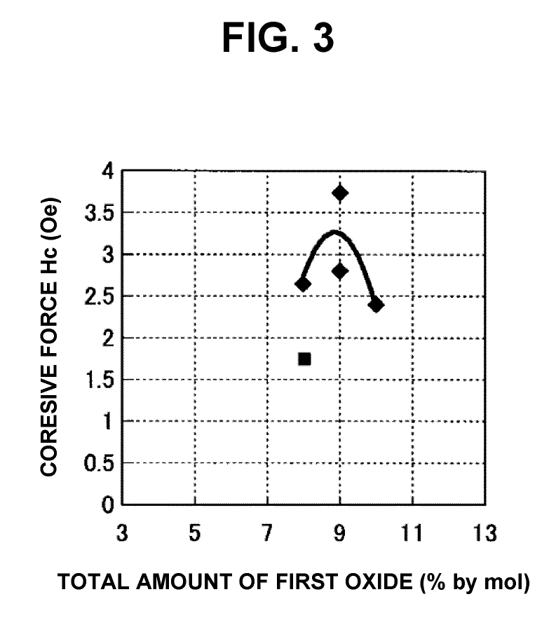

FIG. 3 is a graph illustrating the coercive force of an oxide granular magnetic layer in the first example and the first comparative example. The vertical axis represents the coercive force Hc (Oe) of the oxide granular magnetic layer, and the horizontal axis represents the total amount (% by mole) of the first oxide. The total amount of first oxide is the total amount of TiO₂ and SiO₂ in the first example and the total amount of TiO₂ in the first comparative example. Filled diamonds represent the coercive force Hc in the first example, and a filled square represents the coercive force Hc in the first comparative example.

FIGS. 2 and 3 show that the first example, in which the first oxide contained Ti oxide and Si oxide, had much larger coercive forces Hc than the first comparative example, in which the first oxide was Ti oxide, regardless of the mole fraction ratio of TiO₂ to SiO₂. The larger coercive force Hc in the first example is ascribed to a reduction in the magnetic interaction between magnetic particles. The two oxides TiO₂ and SiO₂ in the first oxide probably promote the separation of the magnetic particles. The first example, regardless of the composition, had a higher Hc/Hk than the first comparative example. This also demonstrates that the two oxides TiO₂ and SiO₂ in the first oxide effectively improve the magnetic characteristics of the magnetic recording medium.

Another effective factor responsible for the improvement in the magnetic characteristics of the magnetic recording medium is probably the second oxide, that is, the Co oxide added to prevent oxygen deficiency. In the absence of the second oxide CoO, TiO₂ and SiO₂ in the first oxide contribute only to the formation of grain boundaries and are not compensated for oxygen deficiency resulting from the decomposition by sputtering. Thus, the combination of oxides will have minor effects. This is also evident from a second example described below.

FIG. 3 shows that the first example had the maximum coercive force Hc at a total amount of first oxide of about 9% by mole and that the first example would have a higher coercive force Hc than the first comparative example at a total amount of first oxide of about 12% by mole or less. FIG. 2 shows that the first example had the maximum coercive force Hc when the molar fractions of TiO₂ and SiO₂ were about 5% and about 4% by mole, respectively. Thus, the lower limits of TiO₂ and SiO₂ are about 3% by mole, and the total amount of TiO₂ and SiO₂ is desirably about 12% by mole. Accordingly, the upper limits of TiO₂ and SiO₂ are about 9% by mole.

Since an excessive amount of TiO₂ added to the oxide granular magnetic layer 19 does not reduce the medium noise, CoO was added to the oxide granular magnetic layer 19 to prevent the oxygen deficiency caused by the penetration of Ti, which was produced by the decomposition of TiO₂, into the magnetic particles. When CoO was added to the oxide granular magnetic layer 19, an increase in the amount of TiO₂ added to the oxide granular magnetic layer 19, for example, from 3% by mole to 6% by mole did not reduce the coercive force Hc of the oxide granular magnetic layer 19, but reduced the magnetic interaction between the magnetic particles and thereby increased the coercive force Hc. Ti produced by the decomposition of TiO₂ is bound to O (oxygen) atoms produced by the decomposition of CoO to form TiO₂. This prevents the reduction in coercive force Hc due to the penetration of Ti into the Co alloy portion. While TiO₂ is decomposed in a certain proportion, the adverse effects of TiO₂ appear above 9% by mole TiO₂ because of the positive effect of TiO₂. However, since TiO₂ is decomposed even at 9% by mole or less TiO₂, CoO is presumed to have a positive effect even at 9% by mole or less TiO₂. Experimental results of the present inventors show that, in terms of the coercive force Hc of the oxide granular magnetic layer 19, the amount of TiO₂ added to the oxide granular magnetic layer 19 ranges preferably from about 3% to about 9% by mole and more preferably from about 3% to about 5% by mole. In this case, the amount of SiO₂ added to the oxide granular magnetic layer 19 ranges from about 3% to about 9% by mole and more preferably from about 3% to about 4% by mole.

The sputtering target used to form the oxide granular magnetic layer 19 may be a single target that contains a Co alloy, such as CoCrPt, a first oxide containing Ti oxide, such as TiO₂, and Si oxide, such as SiO₂, and a second oxide containing Co oxide, such as CoO, or at least two targets each containing at least one of the Co alloy, the first oxide, and the second oxide. The first oxide has a lower energy of formation than the second oxide.

### Second Example

In the second example, a perpendicular magnetic recording medium 1 having the same structure as the first example was produced under the same deposition conditions as the first example. The amount of CoO added to the oxide granular magnetic layer 19 was varied. The oxide granular magnetic layer 19 in the second example contains 92-p % by mole Co₇₂Cr₉Pt₁₉, 5% by mole TiO₂, 3% by mole SiO₂, and p % by mole CoO.

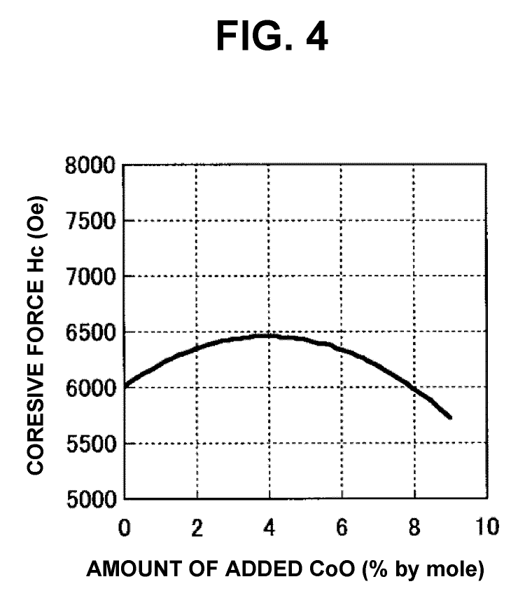

FIG. 4 is a graph illustrating the coercive force Hc of the oxide granular magnetic layer 19 as a function of the amount of CoO added to the oxide granular magnetic layer 19. The vertical axis represents the coercive force Hc (Oe) of the oxide granular magnetic layer 19, and the horizontal axis represents the amount (% by mole) of CoO added to the oxide granular magnetic layer 19. The coercive force Hc was increased at an amount of CoO added to the oxide granular magnetic layer 19 in the range of about 1% to about 8% by mole. This is partly because part of oxygen of CoO added to the oxide granular magnetic layer 19 was bound to Ti produced by the decomposition of TiO₂ and thereby prevented the penetration of Ti into the Co alloy. This is also attributed to a reduction in the magnetic interaction between magnetic particles due to the segregation of CoO.

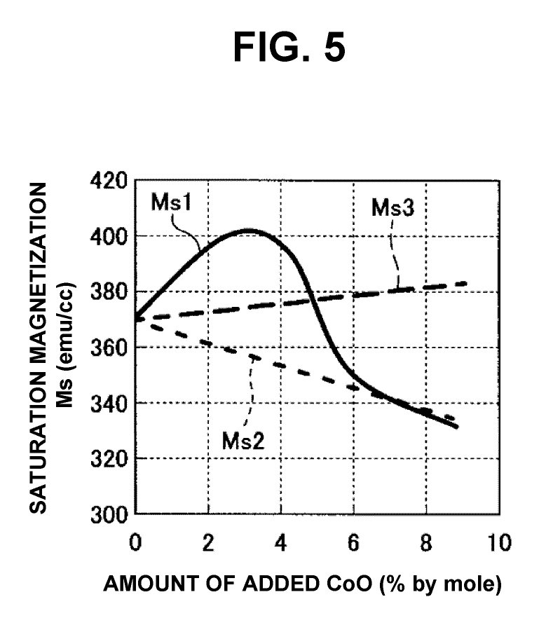

Thus, the saturation magnetization Ms of the oxide granular magnetic layer 19 was measured as a function of the amount of CoO added to the oxide granular magnetic layer 19. FIG. 5 illustrates the measured saturation magnetization Ms1 of the oxide granular magnetic layer 19 as a function of the amount of CoO added to the oxide granular magnetic layer 19. The vertical axis represents the saturation magnetization Ms (emu/cc) of the oxide granular magnetic layer 19, and the horizontal axis represents the amount (% by mole) of CoO added to the oxide granular magnetic layer 19. The saturation magnetization Ms1 increased at an amount of CoO added to the oxide granular magnetic layer 19 in the range of about 1% to about 5% by mole and decreased at an amount of CoO added to the oxide granular magnetic layer 19 of about 6% by mole or more. If CoO added to the oxide granular magnetic layer 19 remains as an oxide in the oxide granular magnetic layer 19, the Co content of the Co alloy portion decreases with the amount of CoO added. In this case, the saturation magnetization Ms will monotonically decrease as shown by a short broken line Ms2. On the other hand, if CoO added to the oxide granular magnetic layer 19 is completely decomposed into Co and oxygen, and the Co is entirely incorporated into the Co alloy, the saturation magnetization Ms will increase with increasing total amount of Co in the oxide granular magnetic layer 19, as shown by a long broken line Ms3. A comparison between the measured saturation magnetization Ms1 and the calculated saturation magnetizations Ms2 and Ms3 shows that the measured saturation magnetization Ms1 is larger than the calculated saturation magnetization Ms2 at an amount of CoO added to the oxide granular magnetic layer 19 in the range of about 1% to about 6% by mole. This indicates that Co resulting from the decomposition of CoO is incorporated into the Co alloy. The measured saturation magnetization Ms1 is larger than the calculated saturation magnetization Ms3 at an amount of CoO added to the oxide granular magnetic layer 19 in the range of about 2% to about 5% by mole. This indicates that 0 (oxygen) atoms resulting from the decomposition of CoO are bound to Ti, thus preventing the penetration of Ti. In particular, the measured saturation magnetization Ms1 is substantially identical to the calculated saturation magnetization Ms2 at an amount of CoO added to the oxide granular magnetic layer 19 of about 6% by mole or more, indicating an insufficient effect of CoO. Taken together, oxygen was effectively supplied at an amount of CoO added to the oxide granular magnetic layer 19 in the range of about 1% to about 6% by mole and more effectively in the range of about 2% to about 5% by mole.

### Third Example

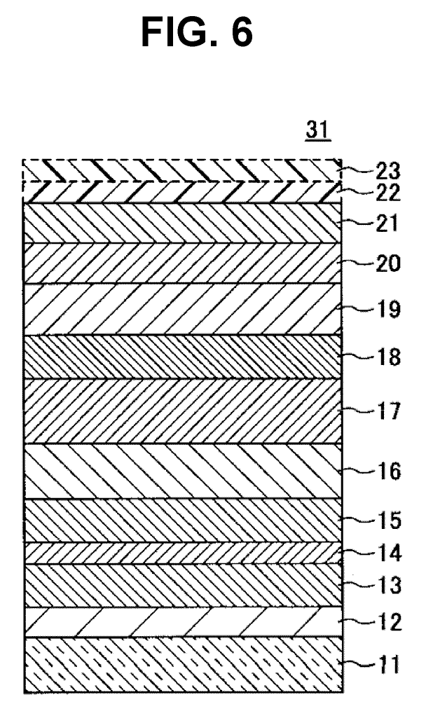

FIG. 6 is a cross-sectional view of a magnetic recording medium according to a third example. In the present example, the present invention is applied to a perpendicular magnetic recording medium. In FIG. 6, the same components as in FIG. 1 are denoted by the same reference numerals and will not be further described. A perpendicular magnetic recording medium 31 included, on a nonmagnetic substrate 11, a CrTi contact layer 12, a CoFeZrTa soft-magnetic layer 13, a Ru coupling layer 14, a CoFeZrTa soft-magnetic layer 15, a NiW seed layer 16, a Ru intermediate layer 17, a nonmagnetic CoCr—SiO₂ granular intermediate layer 18, and a (Co₇₂Cr₉Pt₁₉)_{96-x-y}—(TiO₂)ₓ—(SiO₂)_{y}—(CoO)₄ oxide granular magnetic layer (first magnetic layer) 19. The perpendicular magnetic recording medium 31 further included a CoCrPt—TiO₂ oxide granular magnetic layer (second magnetic layer) 20 and a CoCrPtB magnetic layer (third magnetic layer) 21 to improve the R/W performance. The amount of CoO added to the oxide granular magnetic layer (first magnetic layer) 19 was varied. A DLC protective layer 22 and a fluorine-containing lubricating layer 23 were formed on the CoCrPtB magnetic layer (third magnetic layer) 21 for the evaluation of the R/W performance. A fluorine-containing lubricating layer may be formed on the DLC protective layer 22 also in the first and second examples. The first magnetic layer 19, the second magnetic layer 20, and the third magnetic layer 21 constituted a recording layer of the perpendicular magnetic recording medium 31.

The thicknesses were 5 nm for the CrTi contact layer 12, 25 nm for the CoFeZrTa soft-magnetic layer 13, 0.5 nm for the Ru coupling layer 14, 25 nm for the CoFeZrTa soft-magnetic layer 15, 8 nm for the NiW seed layer 16, 20 nm for the Ru intermediate layer 17, 3 nm for the nonmagnetic CoCr—SiO₂ granular intermediate layer 18, 8 nm for the (Co₇₂Cr₉Pt₁₉)_{96-x-y}—(TiO₂)ₓ—(SiO₂)_{y}—(CoO)₄ oxide granular magnetic layer 19, 5 nm for the CoCrPt—TiO₂ oxide granular magnetic layer (second magnetic layer) 20, and 5 nm for the CoCrPtB magnetic layer (third magnetic layer) 21. Experimental results of the present inventors showed that the perpendicular magnetic recording medium 31 had almost identical characteristics when the thicknesses range from 1 to 30 nm for the CrTi contact layer 12, 10 to 50 nm for the CoFeZrTa soft-magnetic layer 13, 0.3 to 2.0 nm for the Ru coupling layer 14, 10 to 50 nm for the CoFeZrTa soft-magnetic layer 15, 2 to 20 nm for the NiW seed layer 16, 5 to 30 nm for the Ru intermediate layer 17, 1 to 10 nm for the nonmagnetic CoCr—SiO₂ granular intermediate layer 18, 5 to 30 nm for the (Co₇₂Cr₉Pt₁₉)_{96-x-y}—(TiO₂)ₓ—(SiO₂)_{y}—(CoO)₄ oxide granular magnetic layer 19, 1 to 20 nm for the CoCrPt—TiO₂ oxide granular magnetic layer (second magnetic layer) 20, and 3 to 20 nm for the CoCrPtB magnetic layer (third magnetic layer) 21.

Deposition conditions were as follows: the CrTi contact layer 12 to the CoCrPtB magnetic layer (third magnetic layer) 21 were formed by DC magnetron sputtering using an Ar gas as a sputtering gas, and the deposition pressures were 0.67 Pa for the CrTi contact layer 12 to the NiW seed layer 16, 5 Pa for the Ru intermediate layer 17, 3 Pa for the nonmagnetic CoCr—SiO₂ granular intermediate layer 18, 4 Pa for the (Co₇₂Cr₉Pt₁₉)_{96-x-y}—(TiO₂)ₓ—(SiO₂)_{y}—(CoO)₄ oxide granular magnetic layer 19, 4 Pa for the CoCrPt—TiO₂ oxide granular magnetic layer (second magnetic layer) 20, and 0.67 Pa for the CoCrPtB magnetic layer (third magnetic layer) 21. Experimental results of the present inventors showed that the perpendicular magnetic recording medium 31 had almost identical characteristics when the deposition pressures range from 0.1 to 2.0 Pa for the CrTi contact layer 12 to the NiW seed layer 16 and the CoCrPtB magnetic layer (third magnetic layer) 21 and 0.5 to 15 Pa for the Ru intermediate layer 17 to the CoCrPt—TiO₂ oxide granular magnetic layer (second magnetic layer) 20.

The sputtering is not limited to the DC magnetron sputtering and may be DC sputtering or RF sputtering. The sputtering gas is not limited to the Ar gas and may be a Xe gas, a Kr gas, or a Ne gas.

The DLC protective layer 22 having a thickness of 4 nm was formed by plasma chemical vapor deposition (CVD). The fluorine-containing lubricating layer 23 having a thickness of 0.9 nm was formed by dip coating. The deposition methods and the thicknesses of the DLC protective layer 22 and the fluorine-containing lubricating layer 23 are not limited to these.

In a second comparative example, a perpendicular magnetic recording medium was produced under the same deposition conditions as in the third example, except that the oxide granular magnetic layer 19 was a (Co₇₂Cr₉Pt₁₉)_{100-x-y}—(TiO₂)ₓ—(SiO₂)_{y} oxide granular magnetic layer free of CoO.

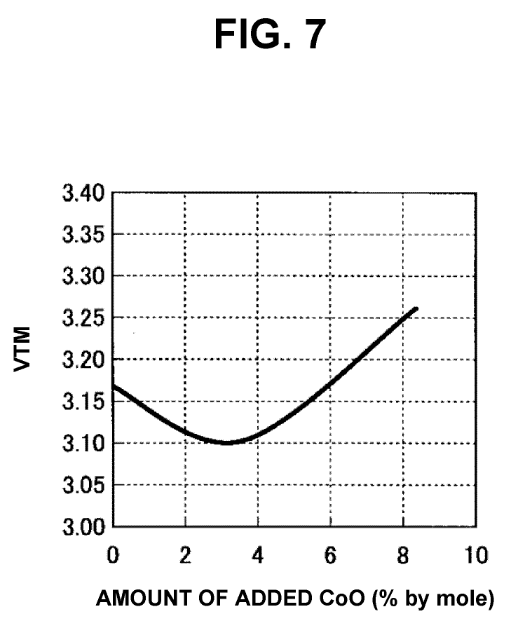

FIG. 7 is a graph illustrating the Viterbi trellis margin (VTM) of the oxide granular magnetic layer (first magnetic layer) 19 as a function of the amount of CoO added to the oxide granular magnetic layer 19. The vertical axis represents the VTM, and the horizontal axis represents the amount (% by mole) of CoO added to the oxide granular magnetic layer (first magnetic layer) 19. The VTM is a signal error rate after the error correction by Viterbi decoding is performed and is proportional to the error rate. A lower VTM indicates better R/W performance of the perpendicular magnetic recording medium 31. In decoding, to clearly differentiate a correct path from a wrong path to improve the quality of reproduced signals, a difference between the metric value (cumulative square error) of the correct path and the metric value of the wrong path is necessarily large. The VTM is defined by the number of cases in which the difference is smaller than a certain threshold. A larger VTM indicates more frequent occurrence of errors. FIG. 7 shows that the addition of CoO to the oxide granular magnetic layer (first magnetic layer) 19 improved the VTM. However, the VTM became worse at an amount of CoO added to the oxide granular magnetic layer (first magnetic layer) 19 of about 6% by mole or more. This is probably because CoO was added as an oxygen source in an excessive quantity. Thus, to achieve excellent R/W performance, the amount of CoO added to the oxide granular magnetic layer (first magnetic layer) 19 ranges preferably from about 2% to about 5% by mole.

The effect of improving the magnetic separation of magnetic particles by an oxide can be achieved by an oxide granular magnetic layer serving as a recording layer. Thus, even if a magnetic layer constitutes a recording layer having a multilayer structure, when the magnetic layer is a granular magnetic layer utilizing an oxide in the magnetic separation of magnetic particles, the aforementioned effects can be achieved. While the present invention was applied to the oxide granular magnetic layer (first magnetic layer) 19 in the present example, experimental results of the present inventors showed that, even when the present invention was applied to the oxide granular magnetic layer (second magnetic layer) 20, the same effect of improving the magnetic separation of magnetic particles was achieved. An improvement in the magnetic separation of magnetic particles in the oxide granular magnetic layer induces an improvement in the magnetic separation of magnetic particles in another magnetic layer formed on the oxide granular magnetic layer. In the present example, therefore, the present invention may be applied only to the oxide granular magnetic layer (first magnetic layer) 19, only to the oxide granular magnetic layer (second magnetic layer) 20, or to both of the oxide granular magnetic layers 19 and 20 (first and second magnetic layers). In all the cases, the aforementioned effects can be achieved.

The magnetic layer (third magnetic layer) 21 was not an oxide granular magnetic layer to further improve the R/W performance.

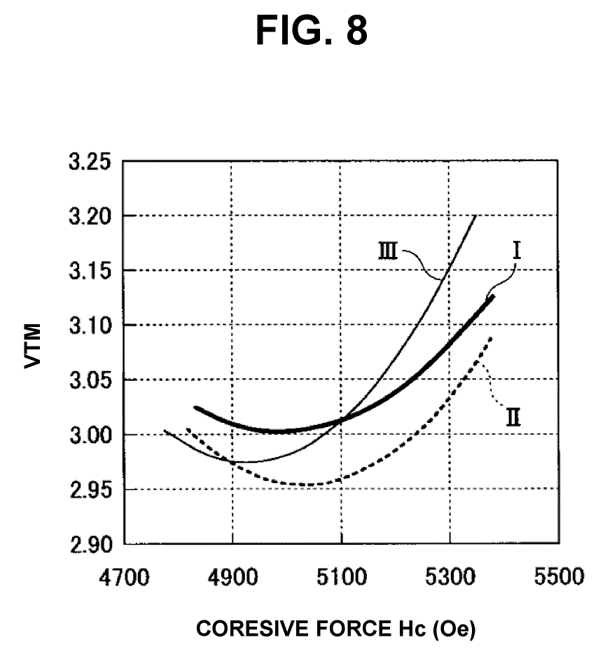

The Ru coupling layer 14 and the CoFeZrTa soft-magnetic layer 15 may be omitted. A modification of the third example in which the Ru coupling layer 14 and the CoFeZrTa soft-magnetic layer 15 were omitted and a third comparative example are described below with reference to FIG. 8. In the third comparative example, a perpendicular magnetic recording medium was produced under the same deposition conditions as in the modification of the third example, except that the oxide granular magnetic layer 19 had a composition of (Co₇₂Cr₉Pt₁₉)₈₈—(TiO₂)₈—(CoO)₄ free of SiO₂.

FIG. 8 is a graph illustrating the VTMs of oxide granular magnetic layers according to the modification of the third example and the third comparative example. The vertical axis represents the VTM, and the horizontal axis represents the coercive force Hc (Oe) of a recording layer composed of a first, second, and third magnetic layers. A curve I shows the VTM of an oxide granular magnetic layer 19 having a composition of (Co₇₂Cr₉Pt₁₉)₈₈—(TiO₂)₅—(SiO₂)₃—(CoO)₄ in the modification of the third example. A curve II shows the VTM of an oxide granular magnetic layer 19 having a composition of (Co₇₂Cr₉Pt₁₉)₈₇—(TiO₂)₆—(SiO₂)₃—(CoO)₄ in the modification of the third example. A curve III shows the VTM of an oxide granular magnetic layer 19 having a composition of (Co₇₂Cr₉Pt₁₉)₈₈—(TiO₂)₈—(CoO)₄ in the third comparative example.

FIG. 8 shows that the modification of the third example, in which the first oxide contained Ti oxide and Si oxide, had lower VTM than the third comparative example, in which the first oxide contained only Ti oxide. The VTM decreased as the total amount of first oxide increased. The VTM in the modification of the third example was close to the VTM in the third comparative example at relatively low coercive forces Hc. This is probably because the magnetic characteristics of the magnetic recording medium were controlled by the thickness ratio of the second magnetic layer to the third magnetic layer formed on the oxide granular magnetic layer. As described above, the oxide granular magnetic layer in the magnetic recording medium according to the first example, in which the first oxide of the oxide granular magnetic layer contained Ti oxide and Si oxide, had much larger coercive forces Hc than the oxide granular magnetic layer in the first comparative example. However, in the modification of the third example, considering the balance between the oxide granular magnetic layer (first magnetic layer) and the second and third magnetic layers, the first magnetic layer had a relatively small thickness. This resulted in small coercive forces Hc of the entire recording layer. Thus, the improvement in VTM in the modification of the third example was not so distinctive.

In these examples, the Co alloy of the first granular magnetic layer 19 and/or the second granular magnetic layer 20 is not limited to CoCrPt and may be CoCr, CoCrTa, CoCrPt-M (M=B, Cu, Mo, Nb, Ta, or W), or an alloy thereof.

In these examples, the present invention is applied to a perpendicular magnetic recording medium. However, the improvement in the magnetic separation of magnetic particles in a magnetic layer is not only for the perpendicular magnetic recording media but also for longitudinal (or in-plane) magnetic recording media. Thus, the present invention can be applied not only to perpendicular magnetic recording media, but also to longitudinal magnetic recording media.

A magnetic recording medium having reduced medium noise can be manufactured by the method for manufacturing a magnetic recording medium.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method for manufacturing a magnetic recording medium including a nonmagnetic substrate, an intermediate layer over the nonmagnetic substrate, and a granular magnetic layer for recording information, disposed on the intermediate layer, the method comprising:
sputtering a Co alloy, a Ti oxide, a Si oxide and a Co oxide simultaneously to form the granular magnetic layer containing Co alloy magnetic particles and an oxide magnetically separating the magnetic particles.

2. The method according to claim 1, wherein the sputtering is carried out by using a target containing a Ti oxide, a Si oxide and a Co oxide.

3. The method according to claim 2, the target further contains a Co alloy.

4. The method according to claim 2, wherein the total amount of the Ti oxide and the Si oxide in the target is about 12% by mole or less.

5. The method according to claim 2, wherein the Ti oxide is TiO₂, and the total amount of TiO₂ in the target ranges from about 3% to about 9% by mole.

6. The method according to claim 2, wherein the Si oxide is SiO₂, and the total amount of SiO₂ in the target ranges from about 3% to about 9% by mole.

7. The method according to claim 2, wherein the Co oxide is CoO, and the total amount of CoO in the target ranges from about 1% to about 6% by mole.

8. The method according to claim 2, wherein the Co oxide is CoO, and the total amount of CoO in the target ranges from about 2% to about 5% by mole.

9. The method according to claims 1, wherein the granular magnetic layer forms a recording layer having a monolayer structure.

10. The method according to claims 1, wherein the granular magnetic layer forms at least one sublayer of a recording layer having a multilayer structure.

11. The method according to claims 1, wherein the intermediate layer includes a Ru intermediate layer and a nonmagnetic CoCr—SiO₂ granular intermediate layer, and the magnetic recording medium is a perpendicular magnetic recording medium.

12. The method according to claim 2, wherein the sputtering is carried out by using a second target containing a Co alloy.

13. The method according to claims 12, wherein each of the target and the second target contains at least one selected from the group consisting of the Co alloy, the Ti oxide, the Si oxide, and the Co oxide.
